(19) United States
(12) Patent Application Publication
(10) Pub. No.: US 2005/0073319 A1
(43) Pub. Date: Apr. 7, 2005

(54) Floating impedance high voltage simultaneously test circuit and test method thereof

(75) Inventors: Yauo-Nan Wang, Taipei (TW); Chien-Chao Chu, Sijhih City (TW); Wen-Chieh Wu, Sanchong City (TW)

Correspondence Address: BUCKNAM AND ARCHER, 1077 Northern Boulevard, Roslyn, NY, 11576-1696, US

(73) Assignee: CHROMA ATE INC.

(21) Appl. No.: 10/766,117

(22) Filed: Jan. 27, 2004

(30) Foreign Application Priority Data
Oct. 2, 2003 (TW) 092127296

(51) Int. Cl. G01R 31/06

(52) U.S. Cl. 324/546

(57) ABSTRACT

The invention relates to a floating impedance high voltage simultaneously test circuit, using two or more sets of conditions capable of simultaneously outputting different source signals to perform simultaneously the high voltage test and the low voltage DC impedance test, so that it is possible to simplify the test procedure of electric products, to reduce the poor yield of the facility, to reduce the test time, and to greatly increase the production efficiency; and to a method of performing the test.

### FIELD OF THE INVENTION

The present invention relates to a method of performing simultaneously test, especially to a circuit and a method having functions of simultaneously performing a high voltage test and a DC impedance test by incorporating a floating DC impedance test apparatus with the output condition of a high voltage test.

### BACKGROUND ART

In the quality inspection of household electric appliance (e.g., heater, hair dryer, . . . and etc.), it is usually necessary to perform the test of a primary DC impedance of an electric product via an electric meter besides the high voltage safety test performed by a voltage durable apparatus.

The conventional test is performed by first conducting a high voltage test, and then changing the test apparatus to conduct a DC impedance test, in certain facility the above voltage durable apparatus is connected to a DC impedance test apparatus via a high voltage relay to form a synthesis test apparatus for conducting test on electric products. The disadvantage of the conventional test apparatus is in that conducting tests with two apparatuses require more human resource and larger workspace while often result in failure of the synthesis test apparatus due to frequent switching of the high voltage relay.

Furthermore, the conventional test system can only perform high voltage tests on primary coil, case and secondary coil of electric parts or products, followed by performing a DC impedance test on the primary coil of the electric parts or products via a resistance meter or multifunctional electric meter. Therefore, the production line must be separated into stages of voltage durable test and DC impedance parameter test using different test apparatuses. With such production line, not only more human resource and facility but also more time are needed to complete the test, therefore it is not easy to increase the efficiency of production.

As described by referring to FIG. 2, though equipped with functions of both high voltage generation means 8 and low voltage DC impedance test means 9, the conventional synthesis test system cannot output both test result simultaneously without conducting high voltage relay 10 isolation and switching between respective functions. Except the limited lifetime of contacts, the mechanical operated high voltage relay often surfers the structural problem of the bad connection caused by the weary and oxidation between switching contacts, thereby results in failure of the conventional synthesis test system.

In view of above ineffectiveness, the inventors have developed inventive floating impedance high voltage simultaneously tests circuit and method of performing the test after intensive investigation into the problem.

### SUMMARY OF THE INVENTION

An object of the present invention is to provide a floating impedance high voltage simultaneously test circuit and method of performing the test, so that it is possible to prevent the operator from electric shock caused by mistakably touching the testing object due to the floating ground connection during the high voltage test and to ensure the safety of the operator.

Another object of the present invention is to provide a floating impedance high voltage simultaneously test circuit and method of performing the test, so that it is possible to simplify the procedure of high voltage test and DC impedance test performed on electric products.

The floating impedance high voltage simultaneously test circuit of the present invention uses two or more sets of condition capable of simultaneously outputting different source signals to perform simultaneously the high voltage test and low voltage DC impedance test, in which conducting a DC impedance test via a floating DC impedance electric meter at the same time of conducting high voltage safety test via a high voltage generator, that is conducting synchronized tests of safety and DC impedance on electric parts or products. With high voltage durable isolation condition, the floating DC impedance electric meter has a characteristic capability of performing independently and individually controllable test of DC impedance under high voltage output mode.

### BRIEF DESCRIPTION OF DRAWINGS

The above and other objects, features, and advantages of the present invention will become more apparent from the detailed description in conjunction with the following drawings:

FIG. 1 is a circuit block diagram showing the floating impedance high voltage simultaneously test system in accordance with the present invention.

FIG. 2 is a circuit block diagram showing a conventional synthesis tester.

### DETAILED DESCRIPTION OF THE INVENTION

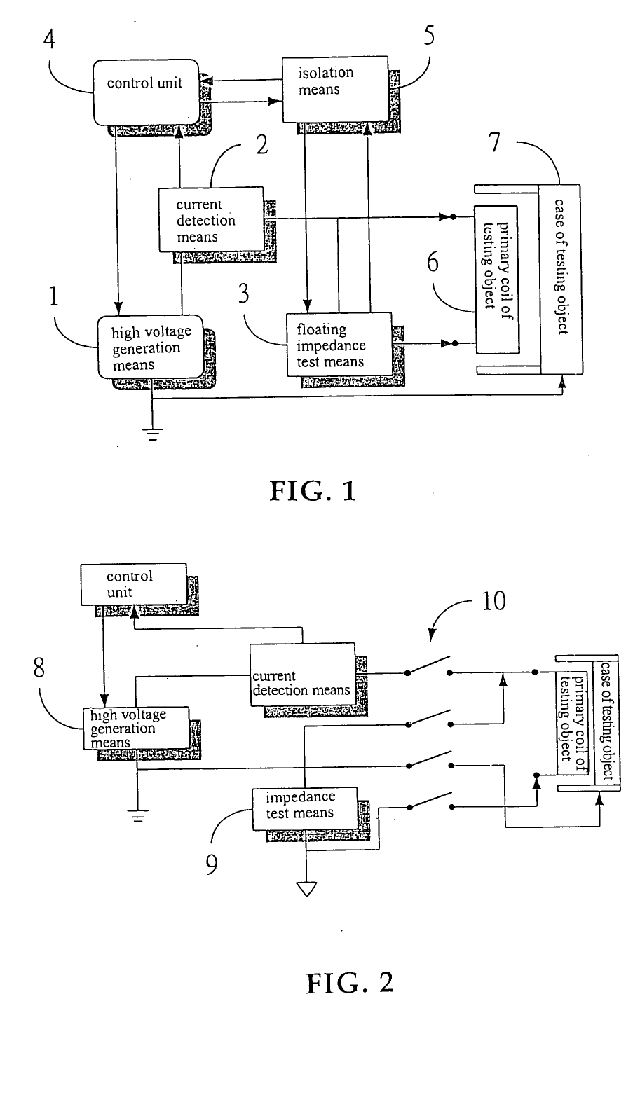

Referring to FIG. 1, a floating impedance high voltage simultaneously test system of the present invention comprises: a high voltage generation means 1 for independently controlling voltage output; a current detection means 2 for detecting current generated by the high voltage generation means by flowing through the testing object; a floating impedance test means 3 for measuring the floating impedance of the primary coil or thermal filament of the testing object; a primary coil 6 of the testing object, such coil may be a coil in motor or a thermal filament in electric heater; a case portion 7 of the testing object; a controller unit 4 for controlling the operation of the high voltage generation means, current detection means and floating impedance test means; and a isolation means 5 for isolating said controller unit from the floating impedance test means. The detailed description of the effect and action provided by above parts is given below.

The high voltage generation means 1 generates a test voltage required by a safety regulation of electric products, usually from one to several thousands volts, and sufficient test current, usually from one to several tens milliamp. The test voltage can be a direct current or an alternative current voltage.

The current detection means 2, which is responsible for the detection of current generated by the high voltage generation means by flowing through the testing object, determines whether there is any unfulfilled safety regulation caused by the manufacture deficiency or current leakage of parts.

The floating impedance test means 3 must be a floating DC impedance test means for measuring the impedance of the primary coil or thermal filament of electric products. The floating impedance test means 3 must have a floating voltage higher than the maximum voltage generated by the high voltage generation means 1 and a floating current lower than the leakage current of the testing products or the leakage current generated by the floating impedance test apparatus must be automatically subtracted by the current detection means 2.

The primary coil 6 of the electric products varies as the testing objects such as coil in motor or thermal filament in heater changed.

The case 7 of the testing object are mostly made of metal, therefore the current leakage caused by bad insulation of coil in motor or thermal filament in heater can be transferred to the metal case and resulted in electric shock on human body. Therefore all electric products must pass the high voltage safety test to ensure no current leakage occurred on the metal case under ordinary working voltage.

When conducting the test, the controller unit 4, which is responsible for controlling the operation of the high voltage generation means, current detection means and floating impedance test means, performs high voltage test on the testing object, and determines whether it is a good products or not by current value read by the current detection means 2 so as to achieve the object of conducting safety test on electric products. At the same time, a control signal is sent from the controller unit 4 to the floating impedance test means 3 via a isolation means 5 so as to conduct a impedance test, while the test data measured by the floating impedance test means 3 is returned to the controller unit 4 via the isolation means 5.

The isolation means 5, which is responsible for isolating the controller unit 4 from the floating impedance test means 3, conducts a impedance test by the impedance test means under a floating mode, while returns the test result to the controller unit 4 via the isolation means 5. Because no high voltage relay is used, it is then possible to completely remove the problem caused by relay failure and to speed up the test perform on electric products.

The test circuit/method of the present invention uses two or more sets of condition capable of simultaneously outputting different source signals to perform simultaneously the high voltage test and the low voltage DC impedance test, so that it is possible to simplify the test procedure of electric products, to reduce the poor yield of the facility, to reduce the test time and to greatly increase the production efficiency. Therefore, the multiple operations of the conventional test are reduced to a simultaneous operation capable of completing the test on electric products with less time while providing safety protection for operators.

The present invention can also resolve the following problems:
1. Reducing time needed to complete the test on electric products.
2. Simplifying the operation stage of the production line so as to increase the efficiency.
3. Improving the synthesis test system by solving the problem of need to temporary stop the production line due to the failure of the high voltage relay.

Summing up the foregoing, the present invention has the industrial applicability and advancement of novel unpublished feature that fulfills the regulation criteria No. 19 and 20 of R.O.C. Patent Law. It should be understood that present invention is not limited to above description made to one of the preferred embodiments and the equivalent changes and modifications of present invention are considered to fall within claims as follows:

### DESCRIPTION OF SYMBOL

1 high voltage generation means
2 current detection means
3 floating impedance test means
4 control unit
5 isolation means
6 primary coil (of testing object)
7 case (of testing object)
8 high voltage generation means
9 impedance test means
10 high voltage reply

1. A floating-impedance high voltage simultaneously test method, characterized in that using two or more sets of condition capable of simultaneously outputting different source signals to perform simultaneously the high voltage test and low voltage DC impedance test, in which conducting a DC impedance test via a floating DC impedance electric meter at the same time of conducting high voltage safety test via a high voltage generation means, that is conducting synchronized tests of safety and DC impedance on electric parts or products.

2. The test method as set forth in claim 1, wherein said floating DC impedance test apparatus has a floating voltage higher than the maximum voltage generated by said high voltage generation means and a floating current lower than the leakage current of the testing products or the current detection means may automatically subtracted the leakage current generated by the floating impedance test apparatus.

3. A floating-impedance high voltage simultaneously test circuit, for conducting simultaneously safety test on primary coil and case of a testing object, comprises:
a high voltage generation means for generation of a required test voltage for safety test for the testing object;
a current detection means for detecting current generated by said high voltage generation means by flowing through the testing object;
a floating impedance test means for measuring the floating impedance of the primary coil or thermal filament of the testing object;
a isolation means for isolating said controller unit from said floating impedance test means to conduct a impedance test by said impedance test means under a floating mode;
a control unit for controlling the operation of above means; wherein by using a combined circuit constituted of above means, said high voltage generation means generates a high voltage required by a high voltage test to conduct a test on a testing object, and determines good/failure of a product with current value read by said current detection means; at the same time, a control signal is sent from said controller unit to said floating impedance test means via the isolation means for conducting a impedance test, while test data measured by said floating impedance test means is returned to said controller unit via said isolation means.
